(19) United States
(12) Patent Application Publication
(10) Pub. No.: US 2007/0075382 A1
(43) Pub. Date: Apr. 5, 2007

(54) Integrated circuit and method for manufacturing the same

(75) Inventors: Keiichi Yamaguchi, Anpachi-gun (JP); Seiji Kai, Anpachi-gun (JP)

Correspondence Address: OLIFF & BERRIDGE, PLC, P.O. BOX 19928, ALEXANDRIA, VA, 22320, US

(73) Assignee: SANYO ELECTRIC CO., LTD., MORIGUCHI-SHI (JP)

(21) Appl. No.: 11/527,572

(22) Filed: Sep. 27, 2006

(30) Foreign Application Priority Data
Sep. 30, 2005 (JP) 2005-286516

(51) Int. Cl. H01L 29/76; H01L 29/94; H01L 31/00; H01L 21/336

(52) U.S. Cl. 257/408; 438/257

(57) ABSTRACT

An integrated circuit is provided, and in the integrated circuit, a microlens array is formed with a silicon nitride film which provides an interlayer insulation film for Al wiring, so that any stress migration in the Al wiring and any deformation of lens shape can be prevented. A silicon nitride film is formed on a semiconductor substrate as an interlayer insulation film between a first-layer wiring and a second-layer wiring. The silicon nitride film includes, in an image pickup section, a lens array having a plurality of convex lenses which are formed with a surface of the silicon nitride film. A silicon dioxide film is grown on the silicon nitride film. Then, a second Al film is formed on the silicon dioxide film. The Al film is etched in an unnecessary portion such as the surfaces of the lens array, to form wiring.

### BACKGROUND OF THE INVENTION

1. Field of the Invention

The present invention relates to an integrated circuit which is provided with a microlens, and in particular to a method for forming a lens array and wiring.

2. Description of the Related Art

In recent years, CCD (Charge Coupled Device) image pickup devices and CMOS (Complementary Metal-Oxide Semiconductor) image pickup devices are required to be configured with an increased number of pixels. In order to achieve an image pickup device having an increased number of pixels with the size of the image pickup device being kept as compact as ever or being reduced, which is especially required in a compact image pickup apparatus used in mobile equipment such as cell phones, an area of a cell which constitutes a pixel to receive light needs to be reduced.

Such a reduced cell area causes a reduction in the area of a light receiving portion in a cell, and lowers the sensitivity of the image pickup device. To solve this problem, a structure having microlenses which are formed corresponding to each cell of an image pickup device is known. The microlenses provide a wider area than a light receiving portion to collect light into the light receiving portion for generating information charges, thereby preventing lowering of the sensitivity of the image pickup apparatus.

The microlens can be formed by using a transparent resin layer which is laminated on an image pickup device after wiring is formed on the image pickup device. Alternatively, the microlens can be formed by using an interlayer insulation film for example, before any wiring is formed. FIG. 1 is a cross sectional view schematically showing a solid state image pickup device which is formed by the latter method. A silicon semiconductor substrate 2 has a light receiving portion (not shown) formed thereon, and the semiconductor substrate 2 has a silicon dioxide film 4 formed on a surface thereof. A metal film, for example an aluminium (Al) film, is deposited on the silicon dioxide film 4 as a first wiring layer (wiring forming film). The wiring layer is patterned to form a first-layer wiring 6, on which a transparent interlayer insulation film 8 is formed.

The interlayer insulation film 8 is made of silicon nitride (Si₃N₄) which has a refractive index higher than that of silicon dioxide (SiO₂). A plurality of convex portions 10 are formed on a surface of the interlayer insulation film 8 in an image pickup section of the image pickup device, each of which provides a convex lens in a lens array. The interlayer insulation film 8 is interposed between the first-layer wiring 6 and second-layer wiring 12 which is formed above the first-layer wiring 6, in a circuit region where wiring is to be formed, to insulate between the wiring 6 and the wiring 12. A wiring forming film consisting of metal for forming the second-layer wiring 12 covers the image pickup section which has the lens array, in addition to the circuit region. The second-layer wiring 12 is formed by patterning the wiring forming layer. After the forming of the second-layer wiring 12, a planarizing film 16 composed of a resin and the like, and a color filter (not shown) on the planarizing film 16 are formed on the surface of the image pickup device.

The resin of the planarizing film 16 has a refractive index which is lower than that of silicon nitride, and the difference between the refractive indexes enables each convex portion 10, being formed of silicon nitride, to function as a lens: each convex portion refracts light incident to the image pickup section at the surface thereof to direct the light to the light receiving portion which is located immediately below the convex portion. In this way, the image pickup section of the image pickup device has a structure having convex lenses which correspond to an array of the light receiving portions on the semiconductor substrate 2, resulting in the structure forming a lens array. Each lens preferably has an area as large as possible to enhance the efficiency of light collection. Thus, in the lens array, adjacent lenses are closely arranged with minimum spaces therebetween.

In a structure shown in FIG. 1, after forming the second-layer wiring 12, a relatively thin silicon nitride film 14 is formed on a surface of a device prior to forming of a planarizing film 16. In this case, the interlayer insulation film 8 and the silicon nitride film 14 constitute a convex lens as a unit.

Generally, wiring which is formed in contact with a silicon nitride film is likely to cause defects such as breakage during a manufacturing process of the device or after the process due to aging over time. This is believed to occur because a cycle of mechanical stress acts on the wiring and stress migration is likely to be caused for reasons including that the silicon nitride film has a relatively high coefficient of thermal expansion. Especially, stress migration easily occurs in Al wiring.

Furthermore, in a lens array having a concave-convex structure at the surface thereof, the shape of lenses tends to be deformed when the wiring forming film, which often remains stuck in concave portions of the structure, is preferably removed from the concave portions of the structure during patterning of the wiring forming film formed on the silicon nitride film. This problem readily occurs particularly in a lens array having convex lenses which are closely arranged. Specifically, at the surface of the interlayer insulation film 8 having the lens arrays, narrow trough-like grooves 18 between convex surface of the lenses, such as a V-shaped groove, are formed at the boundaries of the closely arranged convex lenses. The wiring forming film formed on the interlayer insulation film 8 tends to remain in the grooves 18 when the wiring forming film is etched for patterning. On the contrary, since the silicon nitride film may be relatively easily abraded by the etching depending on a method for etching, a deep etching for a preferable removal of the wiring forming film in the grooves 18 causes etching of a part of the silicon nitride film. This results in a deformed lens shape, which in turn leads to inconveniences such as lowered efficiency of light collection.

The above problems are not limited to the case using an interlayer insulation film for forming a lens array which is formed of only silicon nitride, but may also occur in a case using an interlayer insulation film formed of silicon oxynitride which is a mixture of silicon nitride and silicon oxide, or in a case using an interlayer insulation film formed of other materials which have a high coefficient of thermal expansion and a high etching rate in an etching process of a wiring forming film while lenses having a high refractive index can be formed thereon.

### SUMMARY OF THE INVENTION

The present invention provides an integrated circuit such as a solid state image pickup device in which both a lens array and wiring can be preferably formed in a simple structure.

The present invention provides an integrated circuit which has, on a substrate, a lens region for forming a lens array, and a circuit region located adjacent to the lens region for forming wiring by patterning a wiring forming film, comprising: a first transparent insulation film which is formed on the lens region and the circuit region and forms a plurality of lenses having a convex or concave surface individually in the lens region; and a second transparent insulation film which is formed on the first transparent insulation film, wherein the wiring forming film is formed on the second transparent insulation film. The second transparent insulation film has a lower etching rate than that of the first transparent insulation film in an etching process for patterning the wiring forming film or a lower refractive index than that of the first transparent insulation film, or can restrain stress migration in wiring which is formed thereon better than the first transparent insulation film can.

The present invention provides a method for manufacturing an integrated circuit which has, on a substrate, a lens region for forming a lens array and a circuit region located adjacent to the lens region for forming wiring by patterning a wiring forming film, comprising: forming a first transparent insulation film on the lens region and the circuit region; forming the lens array by forming undulation in a surface of the first transparent insulation film formed on the lens region; forming a second transparent insulation film on the first transparent insulation film in the lens region and the circuit region; forming the wiring forming film on the second transparent insulation film; and forming the wiring by etching the wiring forming film in an unnecessary region which includes at least the lens region, wherein the second transparent insulation film is formed of a material which contains a higher percentage of silicon oxide than that of the first transparent insulation film and has a lower etching rate than that of the first transparent insulation film in an etching process for patterning the wiring forming film.

### BRIEF DESCRIPTION OF THE DRAWINGS

FIG. 1 is a schematic cross sectional view showing a solid state image pickup device in which a lens array is formed prior to forming a topmost wiring layer;

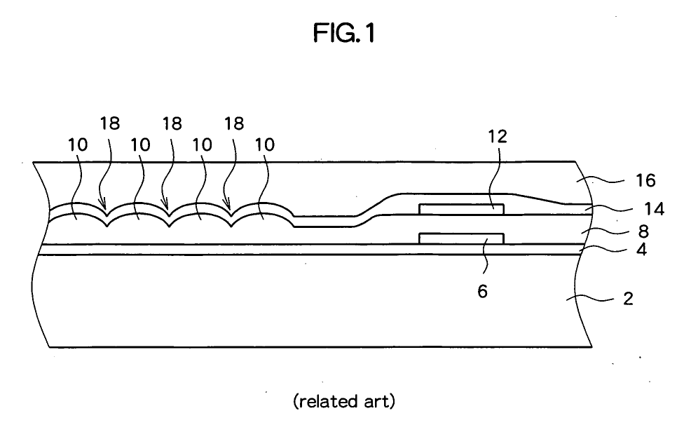

FIG. 2 is a schematic view illustrating a cross section of an embodiment of a solid state image pickup device according to the present invention;

FIGS. 3A-3D are schematic views showing cross sections of an embodiment of a solid state image pickup device according to the present invention in main manufacturing processes;

FIGS. 4A-4C are schematic views showing cross sections of an embodiment of a solid state image pickup device according to the present invention in main manufacturing processes; and

FIGS. 5A-5C are schematic views showing cross sections of an embodiment of a solid state image pickup device according to the present invention in main manufacturing processes.

### DETAILED DESCRIPTION OF THE PREFERRED EMBODIMENT

Now, an embodiment of the present invention will be explained below with reference to the accompanying drawings.

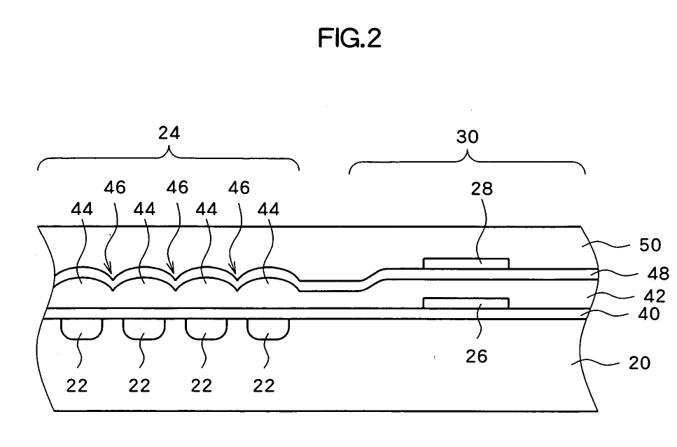

FIG. 2 is a schematic view illustrating a cross section of an embodiment of a solid state image pickup device according to the present invention. In FIG. 2, a silicon semiconductor substrate 20 includes an image pickup section 24 and a circuit region 30 on a surface thereof. The image pickup section 24 has a plurality of light receiving portions 22 arrayed on a surface of the semiconductor substrate 20, and the circuit region 30 is located outside of the image pickup section 24 and is to be provided with wirings 26 and 28.

A silicon dioxide film 40 is formed on the surface of the semiconductor substrate 20 in a process such as thermal oxidation. The silicon dioxide film 40 may be formed in separate processes for the image pickup section 24 and the circuit region 30 respectively, so that a thin gate oxide film can be formed in the image pickup section 24 and a thick LOCOS(Local Oxidation of Silicon) oxide film can be formed in the circuit region 30 for the silicon dioxide film 40 respectively.

In the circuit region 30, the wiring 26 is formed as a first wiring forming film on the silicon dioxide film 40. There is formed a silicon nitride film 42 to provide an interlayer insulation film for insulating between the wiring 26 and the wiring 28 which is formed as a second wiring forming film above the wiring 26.

The silicon nitride film 42 is also formed on the image pickup section 24. The silicon nitride film 42 is transparent, and has a refractive index higher than those of resins which constitute the silicon dioxide film and the planarizing film. The silicon nitride film 42, by taking advantage of these properties, provides a lens array in the image pickup section 24. The silicon nitride film 42 has a concave-convex portion(which includes plurality of concaves and convexes) on a surface thereof in the image pickup section 24, and the convex portions are configured to form convex surfaces which basically face upwards to provide convex lenses 44, and the concave portions are configured to form generally V-shaped grooves 46 at boundaries between adjacent convex lenses 44. The convex lenses 44 are displaced above each light receiving portion 22, and thereby function to collect light, which enters into the image pickup section 24 from the outside, into the light receiving portions 22.

A silicon dioxide film 48 is deposited on the silicon nitride film 42 by a method such as CVD (Chemical Vapor Deposition). The silicon dioxide film 48 comprises a part of the interlayer insulation film between the wiring 26 and the wiring 28, and the wiring 28 is formed on a surface of the silicon dioxide film 48.

After the formation of the wiring 28, a planarizing film 50 made of silicon dioxide or the like is formed on the silicon dioxide film 48 to planarize irregularities of the device surface, and further a color filter array (not shown) is placed on the planarizing film 50 as needed.

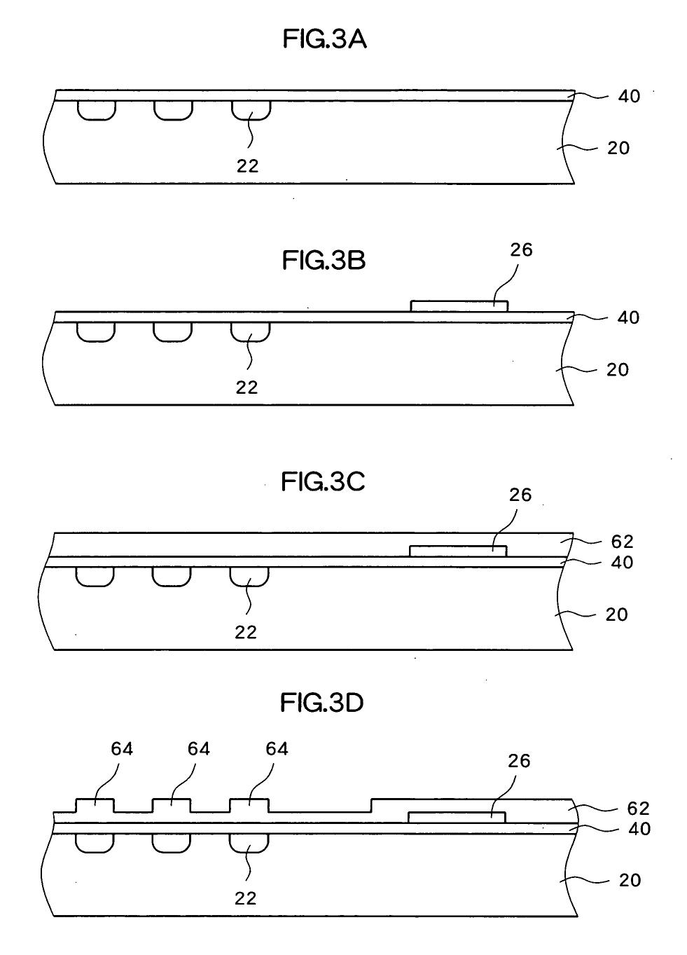

Next, a method for manufacturing a solid state image pickup device having the configuration described above will be explained below. FIGS. 3A-3D, FIGS. 4A-4C, and FIGS. 5A-5C are schematic views illustrating cross sections of a solid state image pickup device in main manufacturing processes of the manufacturing method. Hereinafter, processes after the formation of the light receiving portion 22 on the semiconductor substrate 20 by a well known method and the formation of the silicon dioxide film 40 on the substrate 20 (FIG. 3A) will be explained. A first wiring forming film such as an Al film is grown on the surface of the silicon dioxide film 40 using a PVD (Physical Vapor Deposition) method, for example. On the Al film a photoresist is applied, which is processed to have a pattern corresponding to the wiring 26 in subsequent exposing and developing steps by using a photomask. The Al film is etched by using the patterned photoresist film as a mask, thereby forming the wiring 26 on the circuit region 30 of the substrate 20 (FIG. 3B). The photoresist film is removed after the etching of the Al film.

Once the wiring 26 is formed, a first silicon nitride film 62 is formed (FIG. 3C). The first silicon nitride film 62 may be formed by various film forming technologies including CVD and PVD. Then, a patterned photoresist film is formed on a surface of the silicon nitride film 62 using the same technology as in the case of the above-mentioned Al film. A portion of the photoresist film which corresponds to each light receiving portion 22 and the circuit region 30 remains intact. The remaining portion of the photoresist film is used as a mask in etching the silicon nitride film 62 to form convex portions 64 for each light receiving portion 22. The type of etching may be dry or wet. The convex portions 64 of the silicon nitride film 62 formed by the etching will be the base shape for convex lenses of a lens array, which will be formed in later steps, in the image pickup section 24. The depth of etching in the silicon nitride film 62 is therefore determined depending on a required height of the convex lenses. In FIG. 3D, the silicon nitride film 62 is shown which is etched in a generally vertical direction on the surface of the semiconductor substrate 20 by a dry etching process, but the silicon nitride film 62 may be etched by a wet etching process to form convex portions 64 which have a tapered shape. Alternatively, the silicon nitride film 62 may be etched to form convex portions 64 which have a tapered shape by dry etching.

The convex portions 64 may have any top-view shape depending on the desired top-view shape of convex lenses. From the viewpoint of a lens area which should be as large as possible to enhance the efficiency in light collection, the top-view shape of convex lenses is preferably similar to a cell shape, resulting in enabling the top-view shape of the convex portions 64 to be determined depending on the cell shape. For example, the convex portions 64 may be formed into a rectangular parallelepiped, corresponding to a cell having a rectangular shape.

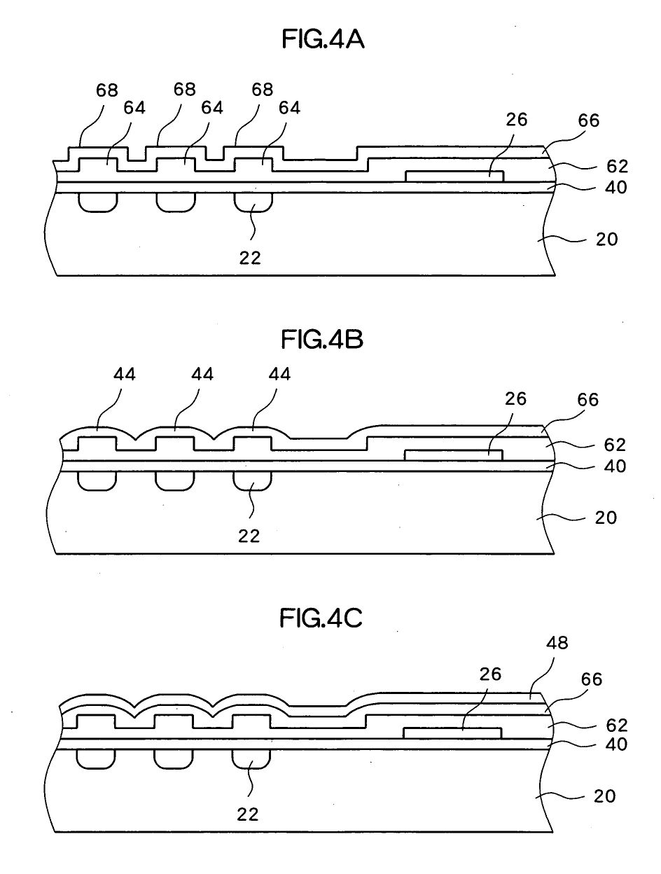

After the convex portions 64 are formed in the image pickup section 24, a second silicon nitride film 66 is formed onto a surface of the silicon nitride film 62 (FIG. 4A). The second silicon nitride film 66 is formed onto a surface of the first silicon nitride film 62 in the image pickup section 24 having the convex portions 64 and in the circuit region 30 by using CVD method, as a film having a generally uniform thickness. The second silicon nitride film 66 may be formed by using any film forming method other than CVD which allows a film having a generally uniform thickness to be formed onto an even surface.

A second silicon nitride film 66 is deposited on the convex portions 64 to form convex portions 68 which are one size larger than the convex portions 64. Then, gas ions are irradiated to the second silicon nitride film 66 having the convex portions 68. The irradiation of gas ions is intended to round off the corners of the convex portions 68. In this embodiment, the gas ions are preferably inert gas ions. The inert gas ions may be argon ions as well as other inert gas ions. In the case of argon ions, after an argon ion plasma is generated and an electric field is produced at the generated plasma, the argon ions are irradiated (impinged) to the second silicon nitride film 66. In this case, the amount of kinetic energy of the argon ions is adjusted so that the kinetic energy causes couplings between surface atoms or molecules to be cut and also allows the atoms or molecules to be recombined with other atoms or molecules in the direction of irradiation (i.e., causes the surface atoms or molecules to move only around the convex portions 68).

After the irradiation of argon ions, the silicon nitride films 62 and 66 form an optically transparent film, as shown in FIG. 4B, where the convex portions 68 of the second silicon nitride film 66 have the corners rounded off, and the off-portions are moved to surround the convex portions 68. This forms curved surface portions of second silicon nitride film 66 over the convex portions 64, and the first and second silicon nitride films 62 and 66 constitute the convex lenses 44 as a unit. The above described step for irradiating gas ions to the formed second silicon nitride film 66 enables the curved surfaces of the convex lenses 44 to be formed extending to the grooves between the convex portions 68, which efficiently forms the lenses having light receiving planes that cover a wide area.

The distance between the convex portions 64 of the first silicon nitride film 62 is defined by the distance of the pattern in the photoresist which is used as a mask in the etching process to form the convex portions 64. Since the distance of the pattern in the photoresist is restrained by the technology of photolithography, the distance can be reduced to a limited extent. Therefore, it is not always possible to set the distance between the convex portions 64 to be small enough to make adjacent lenses share a boundary with each other when gas ions round off the corners of the convex portions 64 to increase the lens areas. On the contrary, according to the configuration of the present invention, the second silicon nitride film 66 covers the convex portions 64 to form the convex portions 68 which are one size larger than the convex portions 64, as a result of which the distance between the convex portions 68 can be made smaller than the distance between the convex portions 64, which facilitates the forming of a lens array having lenses which are closely arranged with the boundaries between the lenses being shared by adjacent lenses.

In this embodiment of a manufacturing method, the silicon nitride film 42 shown in FIG. 2 is constituted with the two silicon nitride films 62 and 66, and the silicon nitride films 62 and 66 form a lens array having a plurality of convex lens which are closely arranged (FIG. 4B). After the lens shapes are formed, a silicon dioxide film 48 is deposited on the silicon nitride film 66 (FIG. 4C).

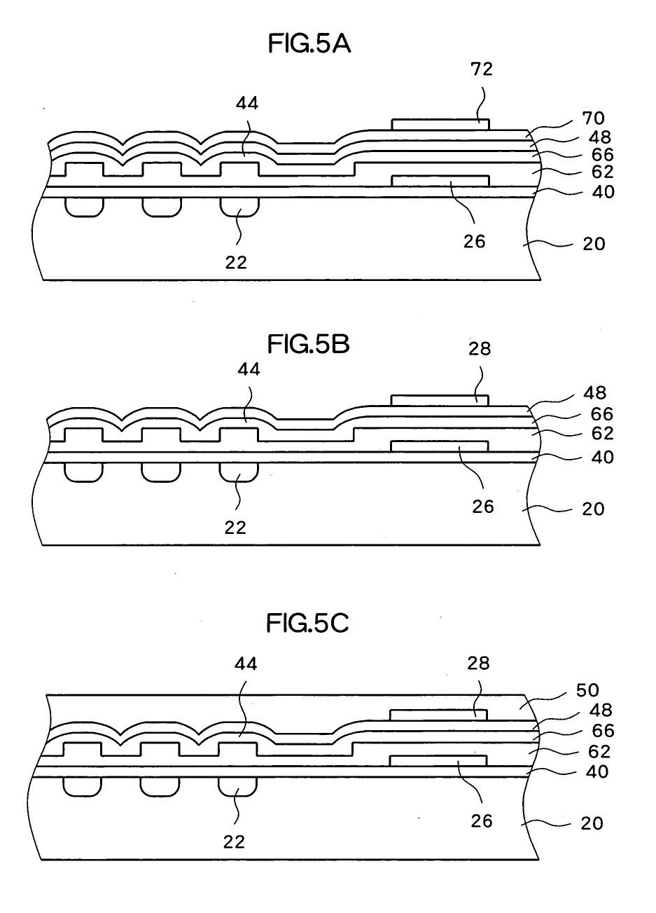

On the surface of the silicon dioxide film 48, a second wiring forming film such as an Al film 70 is grown, using a PVD method for example. A photoresist is applied to the Al film 70A, and processed to have a pattern corresponding to the wiring 28 in subsequent exposing and developing steps by using a photomask, thus forming a photoresist film 72 is formed (FIG. 5A). The Al film 70 is etched by using the photoresist film 72 as a mask, to form the wiring 28 on the silicon dioxide film 48 in the circuit region 30 (FIG. 5B).

The type of etching for wiring forming layer formed of the Al and the like may be dry or wet. However, due to the recent trend toward finer wiring, the dry etching is currently the major type, because more accurate processings can be achieved by dry etching than wet etching. In the manufacturing method of the present invention also, the wirings 26,28 are patterned by dry etching. In a solid state image pickup device of the present invention, the silicon dioxide film 48 formed on the silicon nitride film 42 prevents any deformation of the convex lenses 44 in the etching process for the Al film 70.

When the Al film 70 is etched, the remaining photoresist on the surface of the Al film 70 is removed, and a planarizing film 50 is formed on the Al film 70 (FIG. 5C), thus completing a basic configuration of a solid state image pickup device of the present invention. The planarizing film 50 has a refractive index which is, as in the conventional case, lower than that of the silicon nitride film 42, and also the silicon dioxide film 48 has a refractive index which is close to that of the planarizing film 50 and also lower than that of the silicon nitride film 42. Thus, when light enters from the exterior to the surface of the semiconductor substrate 20, the lights are refracted at the surface of the convex lenses 44 to be collected into the light receiving portions 22. That is, the silicon dioxide film 48 keeps the function of light condensing of the convex lenses 44.

In a solid state image pickup device of the present invention, the silicon nitride film 42 forms the convex lenses 44 which is covered with the silicon dioxide film 48. This silicon dioxide film 48 is the silicon dioxide film which is formed between the silicon nitride film 42 and the wiring 28 to prevent stress migration in the wiring 28 caused by the silicon nitride film 42. That is, the silicon dioxide film to prevent stress migration in the wiring 28 in the circuit region 30 and the silicon dioxide film to protect the shape of the convex lenses 44 in the image pickup section 24 can be formed in one step.

In this embodiment, the silicon dioxide film 48 is deposited on the silicon nitride film 42, but any other film which is made of materials containing other elements in addition to silicon oxide may be deposited on the silicon nitride film 42. Alternatively, instead of the silicon nitride film 42, any other film which contains other elements in addition to silicon nitride may be used to form the convex lenses 44 and the interlayer insulation film for the wirings 26 and 28. For example, instead of the silicon nitride film 42 and the silicon dioxide film 48, a lower film 42 and an upper film 48, both of which are made of silicon oxynitride, may be used. In this case, the lower film 42 is configured to contain a higher percentage of silicon nitride than the upper film 48, and the upper film 48 is configured to contain a higher percentage of silicon oxide than that the lower film 42, so that the above described prevention of stress migration in the wiring 28 and the protection of the shape and light collecting function of the convex lens 44 can be achieved. The type of the lenses which are formed by the silicon nitride film 42 and the like and are closely arranged is not limited to a convex lens, and a concave lens may be used. In this case also, the etching level into the Al film for wiring formation may vary due to the concavity and convexity in the surface of the lens array. Therefore, a lamination of a film which has a relatively low etching rate to the lens forming film such as the silicon nitride film 42 prevents any deformation of the lens shape.

In the above explanation, the present invention is embodied in a solid state image pickup device, but the present invention may be applied to other integrated circuits which include a microlens array, such as a display apparatus.

As explained above by way of the example of a solid state image pickup device, the present invention relates to an integrated circuit which has, on a substrate, a lens region for forming a lens array of a plurality of lenses, and a circuit region located adjacent to the lens region for forming a wiring by patterning a wiring forming film. An integrated circuit of the present invention comprises: a first transparent insulation film which is deposited on the lens region and the circuit region and forms the plurality of lenses having a convex surface or concave surface individually in the lens region; and a second transparent insulation film which is deposited on the first transparent insulation film. The wiring forming film is deposited on the second transparent insulation film. The second transparent insulation film has a lower etching rate than that of the first transparent insulation film in an etching process for patterning the wiring forming film or a lower refractive index than that of the first transparent insulation film, or can restrain stress migration in wiring which is formed thereon better than the first transparent insulation film can. The second transparent insulation film can be formed by a film which contains a higher percentage of silicon oxide than the first transparent insulation film.

The present invention can be preferably applied to an integrated circuit which has the lens array having the plurality of lenses closely arranged. In the lens array having the plurality of lenses which are closely arranged, for example, adjacent lenses can be disposed so that the edges of the convex surfaces or the concave surfaces of the lenses are in contact with each other.

A preferred aspect of the present invention is an integrated circuit, in which the substrate is a semiconductor substrate and the lens region constitutes an image pickup section where a light receiving pixel for generating a signal charge corresponding to an amount of received light is formed in the semiconductor substrate for each of the lens, that is, the above described solid state image pickup device.

The present invention provides a method for manufacturing an integrated circuit which has, on a substrate, a lens region for forming a lens array, and a circuit region located adjacent to the lens region for forming wiring by patterning a wiring forming film, comprising: depositing a first transparent insulation film on the lens region and the circuit region; forming the lens array by forming undulation on a surface of the first transparent insulation film deposited on the lens region; depositing a second transparent insulation film on the first transparent insulation film in the lens region and the circuit region; forming the wiring forming film on the second transparent insulation film; and forming the wiring by etching the wiring forming film in an unnecessary region which includes at least the lens region. The second transparent insulation film is formed of a material which contains a higher percentage of silicon oxide than that of the first transparent insulation film and has a lower etching rate than that of the first transparent insulation film in an etching process for patterning the wiring forming film.

According to the present invention, a second transparent insulation film which contains silicon oxide is deposited on a surface of a first transparent insulation film which forms a concavo or convex structure of lenses. A wiring forming film is formed on the second transparent insulation film and is patterned to form wiring. Since silicon oxide has a refractive index which is close to that of a planarizing film that has been conventionally disposed in contact with the first transparent insulation film, the second transparent insulation film, which contains a higher percentage of silicon oxide than the first transparent insulation film, basically has a lower refractive index than the first transparent insulation film. Therefore, the second transparent insulation film does not adversely affect the function of the formed convex lenses for collecting flight. Furthermore, silicon oxide has a relatively low coefficient of thermal expansion and a relatively low etching rate in an etching process for general wiring materials. This allows the second transparent insulation film to restrain any stress migration in wiring which is formed thereon, and to restrain any deformation of lens shape due to overetching for removing the wiring forming film which tends to remain in concave portions on the lens array surfaces. Particularly in a lens array having convex lenses which are closely arranged, because V-shaped grooves are formed between the convex lenses, the wiring forming film is likely to remain in the grooves. According to the present invention, even in such a lens array configuration, the wiring forming film can be preferably removed.

1. An integrated circuit which has, on a substrate, a lens region for forming a lens array having a plurality of lenses, and a circuit region located adjacent to the lens region for forming a wiring by patterning a wiring forming film, comprising:
a first transparent insulation film which is formed on the lens region and the circuit region and forms a plurality of lenses having a convex or concave surface individually in the lens region; and
a second transparent insulation film which is formed on the first transparent insulation film,
wherein the wiring forming film is formed on the second transparent insulation film, and
the second transparent insulation film has a lower etching rate than that of the first transparent insulation film in an etching process for patterning the wiring forming film.

2. An integrated circuit which has, on a substrate, a lens region for forming a lens array having a plurality of lenses, and a circuit region located adjacent to the lens region for forming a wiring by patterning a wiring forming film, comprising:
a first transparent insulation film which is formed on the lens region and the circuit region and forms a plurality of lenses having a convex or concave surface individually in the lens region; and
a second transparent insulation film which is formed on the first transparent insulation film,
wherein the wiring forming film is formed on the second transparent insulation film, and
the second transparent insulation film has a lower refractive index than that of the first transparent insulation film.

3. An integrated circuit which has, on a substrate, a lens region for forming a lens array having a plurality of lenses, and a circuit region located adjacent to the lens region for forming a wiring by patterning a wiring forming film, comprising:
a first transparent insulation film which is formed on the lens region and the circuit region and forms a plurality of lenses having a convex or concave surface individually in the lens region; and
a second transparent insulation film which is formed on the first transparent insulation film,
wherein the wiring forming film is formed on the second transparent insulation film, and
the second transparent insulation film can restrain stress migration in wiring which is formed thereon better than the first transparent insulation film can.

4. The integrated circuit according to claim 1, wherein
the second transparent insulation film contains a higher percentage of silicon oxide than the first transparent insulation film.

5. The integrated circuit according to claim 4, wherein
the plurality of lenses in the lens array are closely arranged.

6. The integrated circuit according to claim 5, wherein
the adjacent lenses in the lens array are closely arranged so that the edges of the convex or concave surfaces thereof are in contact with each other.

7. The integrated circuit according to claim 4, wherein
the first transparent insulation film contains a higher percentage of silicon nitride than the second transparent insulation film.

8. The integrated circuit according to claim 4, wherein
the first transparent insulation film is a silicon nitride film, and
the second transparent insulation film is a silicon dioxide film.

9. The integrated circuit according to claim 4, wherein the wiring forming film is an aluminium film.

10. The integrated circuit according to claim 4, wherein
the substrate is a semiconductor substrate, and
the lens region constitutes an image pickup section where a light receiving pixel for generating a signal charge corresponding to an amount of received light is formed on the semiconductor substrate for each of the lens.

11. A method for manufacturing an integrated circuit which has, on a substrate, a lens region for forming a lens array, and a circuit region located adjacent to the lens region for forming wiring by patterning a wiring forming film, comprising:
forming a first transparent insulation film on the lens region and the circuit region;
forming the lens array by forming undulation on a surface of the first transparent insulation film formed on the lens region;
forming a second transparent insulation film on the first transparent insulation film in the lens region and the circuit region;
forming the wiring forming film on the second transparent insulation film; and
forming the wiring by etching the wiring forming film in an unnecessary region which includes at least the lens region,
wherein the second transparent insulation film is formed of a material which contains a higher percentage of silicon oxide than that of the first transparent insulation film and has a lower etching rate than that of the first transparent insulation film in an etching process for patterning the wiring forming film.
